(19) United States
(12) Patent Application Publication
(10) Pub. No.: US 2021/0197448 A1
(43) Pub. Date: Jul. 1, 2021

(54) DEVICE FOR PRODUCING PATTERNS AND DEVICE FOR PRODUCING THREE-DIMENSIONALLY SHAPED ARTICLES

(71) Applicant: KANTATSU CO., LTD., Yaita-shi, Tochigi (JP)

(72) Inventors: Eiji OSHIMA, Yaita-shi, Tochigi (JP); Kazutaka NOBORIMOTO, Tokyo (JP); Akio SAKUMA, Sukagawa-shi, Fukushima (JP)

(21) Appl. No.: 16/640,650

(22) PCT Filed: Nov. 14, 2017
(86) PCT No.: PCT/JP2017/040865

§ 371 Date: Mar. 10, 2021

(30) Foreign Application Priority Data
Aug. 25, 2017 (JP) 2017-161701

(51) Int. Cl. B29C 64/135; B29C 64/268; B33Y 30/00

(52) U.S. Cl. CPC B29C 64/135; B33Y 30/00; B29C 64/268

(57) ABSTRACT

The present invention allows formation of a pattern on sheets of various sizes. A pattern producing device includes: a formation section configured to form a pattern by irradiating a pattern forming sheet with a light beam; a shaping table placed above the formation section, having a first opening to pass the light beam, and configured to mount the pattern forming sheet thereon; a column configured to attach the shaping table thereto; and an adapter located in the shaping table, partially closing the first opening, having a second opening to pass the light beam, and configured to mount the pattern forming sheet thereon.

### TECHNICAL FIELD

The present invention relates to a pattern producing device.

### BACKGROUND ART

In the above technical field, PTL 1 discloses a technique to form a circuit pattern on a sheet of predetermined size.

### CITATION LIST

### Patent Literature

PTL 1: JP 2006-319138 A

### SUMMARY OF INVENTION

### Technical Problem

The technique described in PTL 1 is, however, not capable of forming a pattern on sheets of various sizes.

It is an object of the present invention to provide a technique to solve the above problems.

### Solution to Problem

To achieve the above object, a pattern producing device according to the present invention includes: a formation mechanism configured to form a pattern by irradiating a pattern forming sheet with a light beam;

a shaping table placed above the formation mechanism, having a first opening to pass the light beam, and configured to mount the pattern forming sheet thereon;

a column configured to attach the shaping table thereto; and

an adapter located in the shaping table and configured to mount the pattern forming sheet thereon for positioning of the pattern forming sheet on the first opening.

### Advantageous Effects of Invention

The present invention allows formation of a pattern on sheets of various sizes.

### BRIEF DESCRIPTION OF THE DRAWINGS

FIG. 1 is a side perspective view illustrating configuration of a pattern producing device according to a first embodiment of the present invention.

FIG. 2A is a front perspective view illustrating the overall configuration of a pattern producing device according to a second embodiment of the present invention.

FIG. 2B is a partial enlarged side perspective view illustrating configuration of the pattern producing device according to the second embodiment of the present invention.

FIG. 3A is a perspective view illustrating an example of using an adapter used for the pattern producing device according to the second embodiment of the present invention.

FIG. 3B is a diagram illustrating an example of the adapter used for the pattern producing device according to the second embodiment of the present invention.

FIG. 3C is a diagram illustrating another example of the adapter used for the pattern producing device according to the second embodiment of the present invention.

FIG. 3D is a diagram illustrating still another example of the adapter used for the pattern producing device according to the second embodiment of the present invention.

FIG. 4 is a top view illustrating a pattern formation surface of a pattern formation sheet used for the pattern producing device according to the second embodiment of the present invention.

FIG. 5 is a front perspective view illustrating the overall configuration for shaping a three-dimensional shaped object by the pattern producing device according to the second embodiment of the present invention.

FIG. 6 is a diagram illustrating production of a three-dimensional shaped object by the pattern producing device according to the second embodiment of the present invention.

FIG. 7A is a perspective view illustrating an example of using an adapter used for a pattern producing device according to a third embodiment of the present invention.

FIG. 7B is a diagram illustrating an example of the adapter used for the pattern producing device according to the third embodiment of the present invention.

### DESCRIPTION OF EMBODIMENTS

Embodiments of the present invention are exemplarily described below in detail with reference to the drawings. It should be noted that the configuration, the numerical values, the process flows, the functional components, and the like described in the embodiments below are merely examples and may be freely modified or altered. The technical scope of the present invention is not intended to be limited to the following description.

### First Embodiment

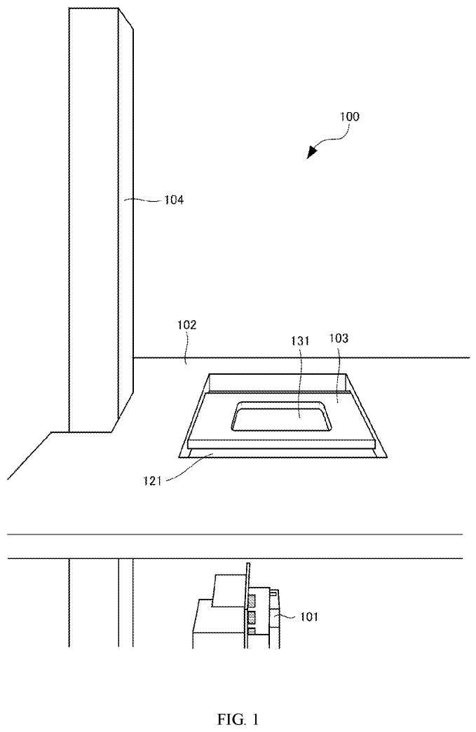

With reference to FIG. 1, a pattern producing device 100 is described as the first embodiment of the present invention. The pattern producing device 100 is a device to produce a pattern using a pattern forming sheet.

As illustrated in FIG. 1, the pattern producing device 100 includes a formation section 101, a shaping table 102, an adapter 103, and a column 104.

The formation section 101 forms a pattern by irradiating a pattern forming sheet with a light beam. The shaping table 102 is placed above the formation section 101, has a rectangular first opening 121 to pass the light beam, and is configured to mount the pattern forming sheet thereon. The column 104 is configured to attach the shaping table 102 thereto. The adapter 103 is located in the shaping table 102 and configured to mount the pattern forming sheet thereon for positioning of the pattern forming sheet on the first opening.

The present embodiment allows formation of a pattern on sheets of various sizes.

### Second Embodiment

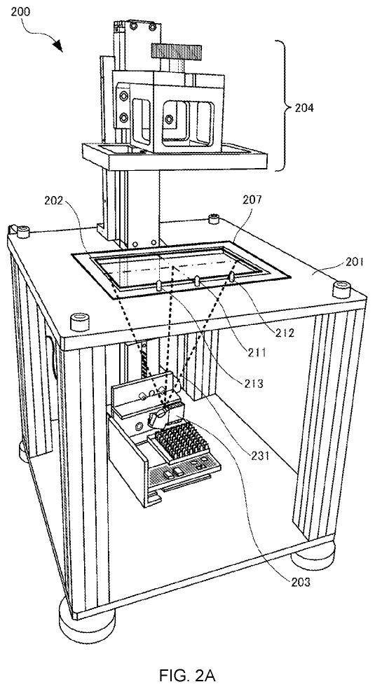

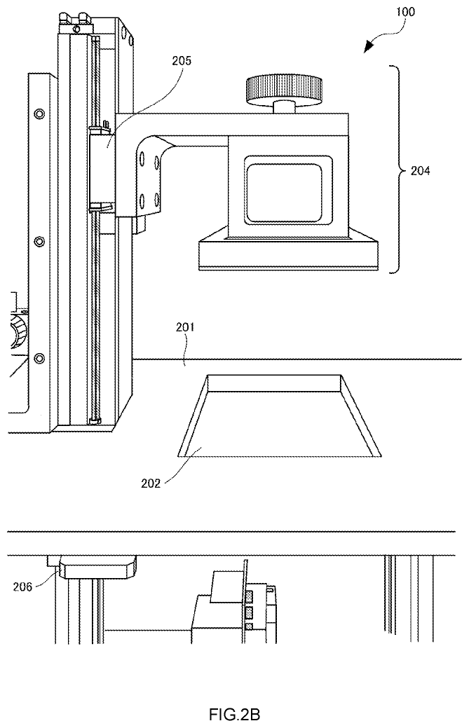

With reference to FIGS. 2A through 6, a pattern producing device 200 according to the second embodiment of the present invention is then described. FIG. 2A is a diagram to illustrate the overall configuration of the pattern producing device 200 according to the present embodiment. FIG. 2B is a partial enlarged side perspective view illustrating configuration of the pattern producing device 200 according to the present embodiment.

The pattern producing device 200 is a device to produce a circuit pattern, a three-dimensional shaped object, and the like. The pattern producing device 200 includes a shaping table 201 (shaping base), a light beam irradiation window 202 (hole), an optical engine 203, a lifting head 204, a head feeding mechanism 205, and a stepping motor 206. The pattern producing device 200 has a size of, for example, 250 mm width×291 mm depth×490 mm height.

On the shaping table 201, a pattern forming sheet 207 is mounted. Although not shown, the pattern forming sheet 207 is provided with a positioning reference hole and rotation preventing holes to match a positioning pin 211 and rotation preventing pins 212 and 213, respectively. For example, the positioning pin 211 has a round shape and the rotation preventing pins 212 and 213 have a rhombic (diamond) shape. The pattern forming sheet 207 is mounted in place on the shaping table 201 by the pins, and once the sheet is thus mounted, its position does not shift.

When a circuit pattern or the like is formed (produced) using the pattern producing device 200, a mixture containing a conductive material and a photocurable resin is applied on the pattern forming sheet 207 to be put on the shaping table 201 and irradiated with a light beam 231 from the optical engine 203. Examples of the conductive material include, but not limited to, silver, gold, copper, platinum, lead, zinc, tin, iron, aluminum, palladium, carbon, and the like. Representative examples of the photocurable resin include ultraviolet curable resins, such as an acrylic resin (polymeric acrylate), a urethane resin (urethane acrylate), a vinyl ester resin, and a polyester alkyd resin (epoxy acrylate). The photocurable resin is not limited to them as long as it is cured by a light beam.

The optical engine 203 is a high-power precise engine. It should be noted that the light beam 231 emitted from the optical engine 203 has a wavelength of 405 nm while the wavelength is not limited to this and may be from 200 nm to 400 nm. The light beam 231 emitted from the optical engine 203 is, but not limited to, focus free.

Although detailed configuration of the optical engine 203 is not shown, the optical engine 203 has a light source, a reflecting mirror, a photodetector, a two-dimensional MEMS (micro electro mechanical systems) mirror, and the like. The optical engine 203 may have two one-dimensional MEMS mirrors instead of the two-dimensional MEMS mirror. The light source has a semiconductor LD (laser diode), a collimator lens, and the like. The semiconductor LD is a laser oscillator element to oscillate an ultraviolet laser beam and the like. It should be noted that the laser oscillator element is not limited to such a semiconductor LD and may be an LED (light emitting diode). The two-dimensional MEMS mirror and one-dimensional MEMS mirrors are driven based on a control signal input from outside and are devices that vibrate to reflect the laser beam by varying the angle in the horizontal direction (X direction) and the vertical direction (Y direction). The optical engine 203 has a WVGA (wide video graphics array) resolution of 720 P or 1080 P, a width of approximately 30 mm, a depth of approximately 19 mm, a height of approximately 6 mm, and a volume of approximately 4.4 cc. One or a plurality of semiconductor LDs may be arranged in the optical engine 203 and a necessary number of semiconductor LDs may be placed arranged in accordance with the application purpose. Although the light beam 231 emitted from the optical engine 203 has a spot size of 75 μm, the spot size may be appropriately changed in accordance with the application purpose.

The shaping table 201 is provided with the light beam irradiation window 202 as a hole to pass the light beam 231. Accordingly, the light beam 231 emitted from the optical engine 203 passes through the light beam irradiation window 202 and irradiates the pattern forming sheet 207 mounted on the shaping table 201. A pattern is thus formed on the pattern forming sheet 207. The light beam irradiation window 202 is an opening portion provided in the shaping table 201 or a hole (through hole) formed in the shaping table 201.

The lifting head 204 is used for producing a three-dimensional shaped object. The lifting head 204 is moved up and down by the head feed mechanism 205 and the stepping motor 206. The head feed mechanism 205 is a high rigidity ball screw feed mechanism. The stepping motor 206 is a high torque stepping motor. It should be noted that the structure for moving up and down the lifting head 204 is not limited to the structure using the head feed mechanism 205 and the stepping motor 206. In addition, the head feed mechanism 205 is not limited to the ball screw feed mechanism.

The head feeding mechanism 205 is a high-rigidity high-speed precision feed mechanism. The head feed mechanism 205 has a feed speed of, for example, 3 kg weight·50 mm/sec·2.5 μm pitch. The lifting head 204 is a high-rigidity lightweight head.

The mixture is applied on the pattern forming sheet 207 by, for example, setting a silk screen film provided with an application area in a screen printer. As another example, instead of using a screen printer, the mixture may be directly applied to the pattern forming sheet 207 using a select roller or the like. The application of the mixture is not limited to these methods.

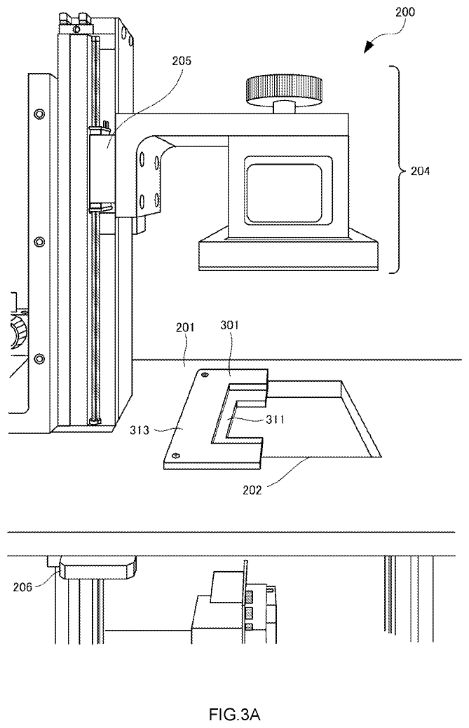

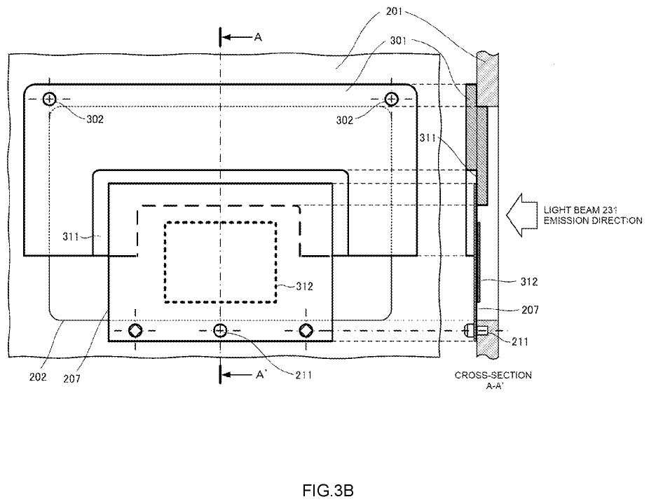

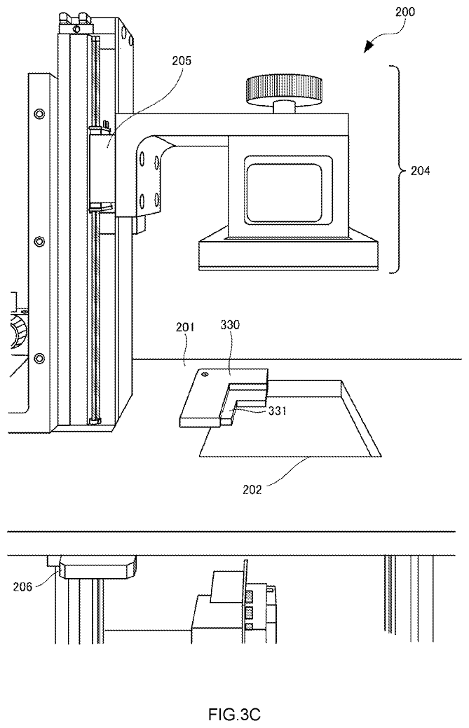

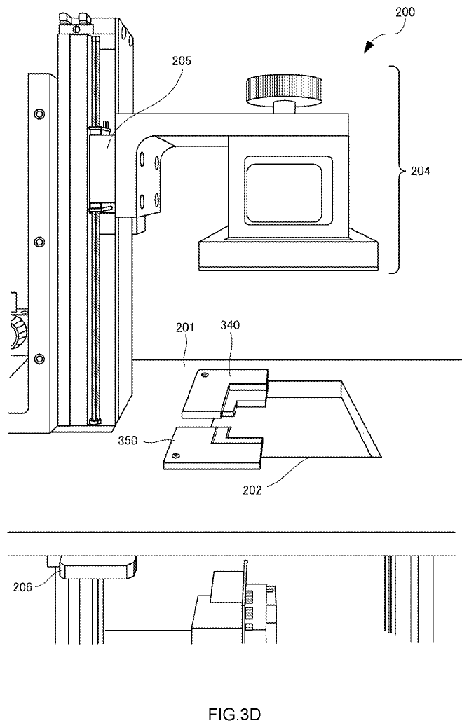

FIG. 3A is a perspective view illustrating an example of using an adapter 301 used for the pattern producing device 200 according to the present embodiment. FIG. 3B is a diagram illustrating an example of the adapter 301 used for the pattern producing device 200 according to the present embodiment. In FIG. 3B, a top view is on the left and a cross-sectional view taken along line A-A′ is on the right.

For example, if the size of the pattern forming sheet 207 is smaller than the light beam irradiation window 202, the pattern forming sheet 207 drops from the light beam irradiation window 202 without any assistance, failing to mount the pattern forming sheet 207 on the shaping table 201. It is thus not possible to shape a small pattern using a small pattern forming sheet 207. On the pattern forming sheet 207, a mixture 312 is applied.

To cope with this situation, the adapter 301 to prevent the pattern forming sheet 207 from dropping is set to partially close the light beam irradiation window 202 of the shaping table 201. That is, the adapter 301 is set on the shaping table 201 to temporarily decrease the size of the opening (hole) formed by the light beam irradiation window 202 and the dropping of the pattern forming sheet 207 is thus prevented.

The adapter 301 has an overall substantially rectangular shape while also having a shape open on one side like a C shape. Although the adapter 301 has an opening in a rectangular shape taken from above, the shape of the opening is not limited to this. Such a shape of the adapter 301 open on one side allows a space to pass the light beam 231 (light beam passing hole) to be secured.

The space allowing the light beam 231 to pass provided in the adapter 301 forms a portion of a light beam passing opening. That is, the light beam irradiation window 202 with the exception of an overlapping area of the light beam irradiation window 202 and the adapter 301 attached to the shaping table 201 becomes a new opening (new light beam irradiation window) of the shaping table 201 when the adapter 301 is attached. This causes a decrease in size of the light beam irradiation window 202 in the shaping table 201 and thus allows a small pattern forming sheet 207 to be set in the shaping table 201.

The adapter 301 also has an overhanging shape allowing holding by one hand in a hand-held portion 313 and mounted on the shaping table 201. The adapter 301 is configured from two areas of an area flush with the shaping table 201 to form a mounting surface 311 and an area mounted on the shaping table 201 to be fixed to the shaping table 201, and the two areas may be integrally formed as one component or formed as separate components.

The opening (open area in C shape) of the adapter 301 may have an arbitrary size. That is, the opening of the adapter 301 may vary in size in accordance with the size of the pattern forming sheet 207. Moreover, the adapter 301 is mounted on the shaping table 201 to partially close the light beam irradiation window 202. The adapter 301 may be simply put on the shaping table 201 or may be fixed to the shaping table 201 by screwing or the like. Since the adapter 301 is removably located in the shaping table 201, it is possible to remove the adapter 301 from the shaping table 201 by, for example, removing screws. The adapter 301 may be mounted and removed as needed.

Since the mounting surface 311 for the pattern forming sheet 207 of the adapter 301 is flush with the shaping table 201, the distance between the optical engine 203 and the pattern forming sheet 207 is constant and thus another calibration and adjustment of the optical engine become unnecessary. As just described, when the mounting surface 311 is flush with the shaping table 201, the optical engine 203 does not have to be adjusted. In contrast, even when the mounting surface 311 is not flush with the shaping table 201, another calibration and adjustment of the optical engine 203 may be performed.

The adapter 301 is provided with positioning reference holes 302 and the adapter 301 may be fixed to the shaping table 201 using, for example, the positioning reference holes 302 and screws. Alternatively, pins for attaching the adapter 301 may be provided on the shaping table 201 to fix the adapter 301 to the shaping table 201 using the attaching pins and the positioning reference holes 302.

FIG. 3C is a diagram illustrating another example of an adapter 330 used for the pattern producing device 200 according to the present embodiment. As illustrated in FIG. 3C, the adapter 330 may be located at one of the four corners of the light beam irradiation window 202. This allows positioning using at least one of the four corners of the pattern forming sheet 207 and thus allows positioning of at least a portion of the pattern forming sheet 207.

FIG. 3D is a diagram illustrating still another example of adapters 340 and 350 used for the pattern producing device 200 according to the present embodiment. As illustrated in FIG. 3D, the adapters 340 and 350 may be placed at two of the four corners of the light beam irradiation window. This allows positioning using two of the four corners of the pattern forming sheet 207 and thus allows positioning of at least a portion of the pattern forming sheet 207. Although not shown, the adapters may be located at three or four of the four corners of the light beam irradiation window 202.

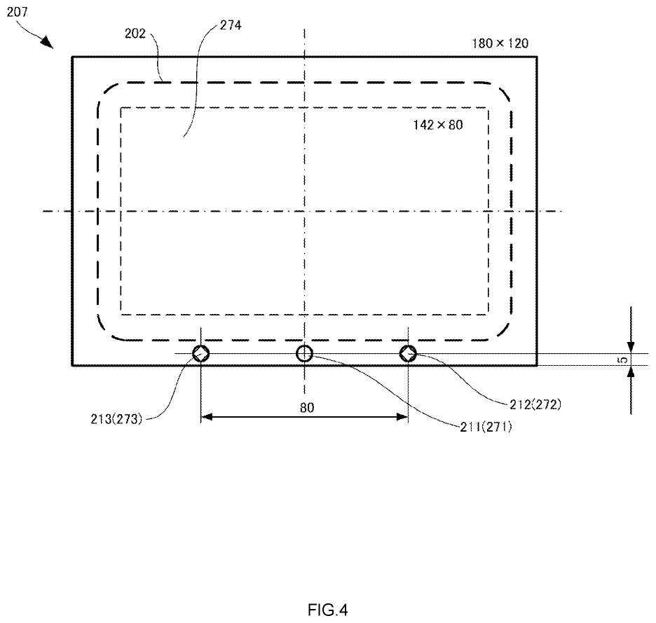

FIG. 4 is a top view illustrating a pattern formation surface of the pattern forming sheet 207 used for the pattern producing device 200 according to the present embodiment. The pattern forming sheet 207 and an application surface of the mixture have a size of, but not limited to, 180 mm×120 mm, for example, and 142×80 mm, respectively. The mixture may be applied on both surfaces of the front and back of the pattern forming sheet 207. The pattern forming sheet 207 has a structure with an application surface 274 of a paste mixture formed on an insulating sheet substrate (PET, PI, etc.). The mixture may be applied on at least either one, for example, the front surface (or the back surface) of the both surfaces of the front and back of the pattern forming sheet 207.

The center of a positioning reference hole 271 and rotation preventing holes 272 and 273 is positioned 5 mm from the bottom side end of the pattern forming sheet 207. The center of the rotation preventing hole 272 is 80 mm away from the center of the rotation preventing hole 273. The positioning reference hole 271 is positioned in the middle of the pattern forming sheet 207. It should be noted that the numerical values, the positions, and the like described here are merely examples and this embodiment is not limited to these numerical values and positions. For example, the positioning reference hole 271 may be provided near the four corners of the pattern forming sheet 207.

The pattern forming sheet 207 with the mixture applied thereon is then set over the light beam irradiation window 202 of the shaping table 201. The pattern forming sheet 207 is set on the shaping table 201 to align the positioning reference hole 271 with the positioning pin 211 provided on the shaping table 201. The positioning pin 211 and the positioning reference hole 271 have circular shapes that are substantially identical and exactly correspond to each other. Instead of using the positioning pin 211 and the positioning reference hole 271, the pattern forming sheet 207 may be simply mounted on the mounting surface 311 of the adapter for positioning. Since the adapter 301 has a height difference, the pattern forming sheet 207 may be positioned using sides or a corner configured from the mounting surface 311 and the height difference of the adapter 301. The positioning pin 211 and the rotation preventing pins may be provided in the adapter 301 or may be provided in both the shaping table 201 and the adapter 301.

The rotation preventing holes 272 and 273 of the pattern forming sheet 207 are set to be aligned with the rotation preventing pins 212 and 213 provided in the shaping table 201. The rotation preventing pins 212 and 213 are diamond locating pins having a rhombic shape, the major axis of the diamond locating pin substantially matches the major axis of each of the elliptical rotation preventing holes 272 and 273, and the pattern forming sheet 207 is reliably fixed on the shaping table 201. It should be noted that the shapes of the rotation preventing pins 212 and 213 and the rotation preventing holes 272 and 273 are not limited to those described above. An example is described above that has the length of the major axis of the diamond locating pin matching the length of the major axis of each of the rotation preventing holes 272 and 273, whereas the lengths of minor axes may match. Although the rotation preventing holes 272 and 273 described here have a horizontally longer elliptical shape, the holes may have a vertically longer elliptical shape, a perfectly circular shape, or the like.

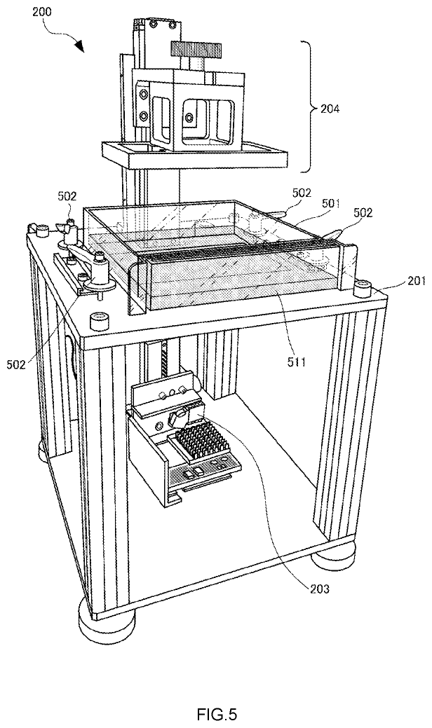

FIG. 5 is a front perspective view illustrating the overall configuration for shaping a three-dimensional shaped object by the pattern producing device according to the present embodiment. Here, production of a three-dimensional shaped object using the pattern producing device 200 is described.

When a three-dimensional shaped object is shaped using the pattern producing device 200, a material tank 501 is attached to the shaping table 201 of the pattern producing device 200. In the material tank 501, a resin 511 to be a material for the three-dimensional shaped object and the like are put and stored. The material tank 501 is removably attached to the shaping table 201 of the pattern producing device 200 with attaching jigs 502. The material tank 501 has a size of, for example, 185 mm×166 mm×34 mm.

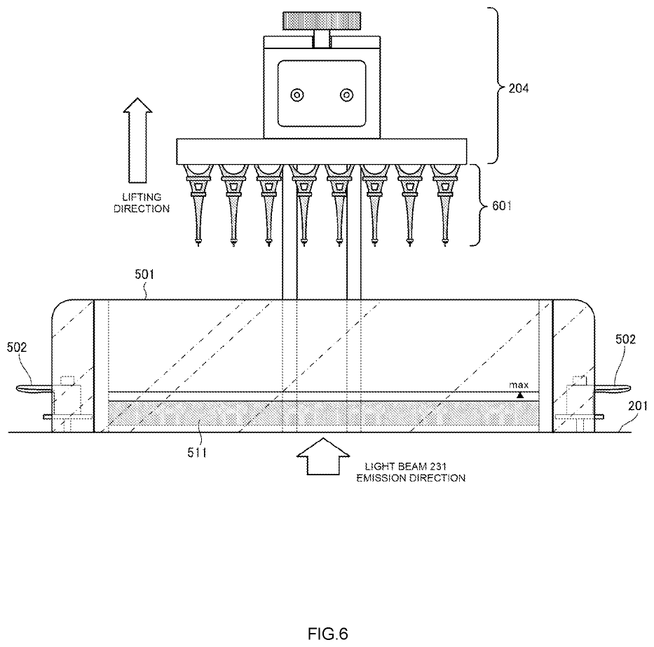

FIG. 6 is a diagram illustrating production of a three-dimensional shaped object by the pattern producing device 200 according to the present embodiment. A three-dimensional shaped object 601 is produced by emitting the light beam 231 from the optical engine 203 towards the material tank 501 and lifting the lifting head 204 in a lifting direction. The speed to lift the lifting head 204 is appropriately determined in accordance with the wavelength and intensity of the light beam 231, the type of material, and the like.

As illustrated in FIG. 6, the pattern producing device 200 allows production of a large number of three-dimensional shaped objects 601. The pattern producing device 200 also allows production of the three-dimensional shaped object 601 with high precision. The lifting head 204 to shape the three-dimensional shaped object 601 has a size of, for example, 140 mm×80 mm.

Since the present embodiment allows use of adapters, pattern forming sheets in various sizes may be used and it is thus possible to form patterns in various sizes.

### Third Embodiment

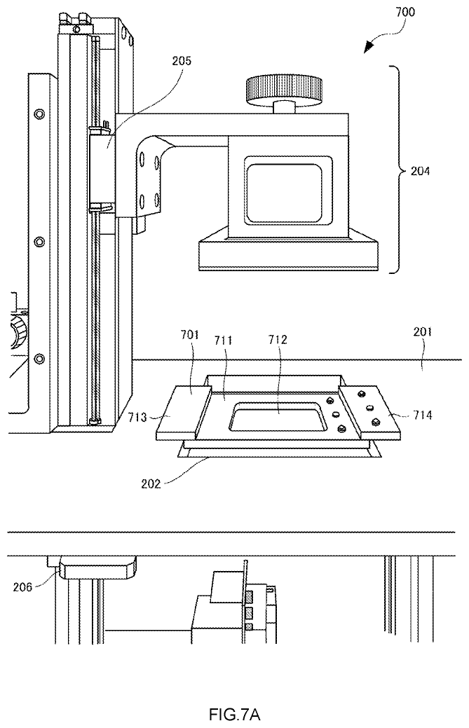

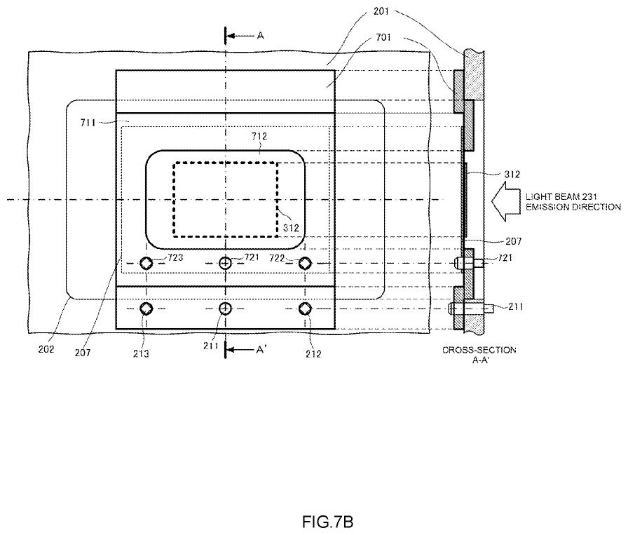

With reference to FIGS. 7A and 7B, an adapter 701 used for a pattern producing device 700 according to the third embodiment of the present invention is then described. FIG. 7A is a perspective view illustrating an example of using the adapter 701 used for the pattern producing device 700 according to the present embodiment. FIG. 7B is a diagram illustrating an example of the adapter 701 used for the pattern producing device 700 according to the present embodiment. The adapter 701 used for the pattern producing device 700 according to the present embodiment differs from the second embodiment in that the adapter has a straddle shape. Since other configuration and operation are same as those in the second embodiment, same reference signs are given to the same configuration and operation to omit the description in detail.

The adapter 701 has a straddle shape allowing holding by both hands in hand-held portions 713 and 714 and is provided with an opening 712 (light beam passing window, through hole) allowing the light beam 231 to pass at the center. Although the opening 712 has a rectangular shape taken from above, the shape of the opening 712 is not limited to this. When the pattern forming sheet 207 is set on a mounting surface 711 of the adapter 701, the area of the pattern forming sheet 207 on which the mixture 312 is applied is positioned over the opening 712. The adapter 701 is configured from two areas of an area flush with the shaping table 201 to form a mounting surface 711 and an area mounted on the shaping table 201 to be fixed to the shaping table 201, and the two areas may be integrally formed as one component or formed as separate components.

The adapter 701 is provided with a positioning pin 721 and rotation preventing pins 722 and 723, and the pattern forming sheet 207 is fixed to the adapter 701 by the positioning pin 721 and the rotation preventing pins 722 and 723. The pattern forming sheet 207 is thus fixed to the adapter 701, thereby being indirectly fixed to the shaping table 201.

The adapter 701 is fixed to the shaping table 201 to partially close the light beam irradiation window 202 of the shaping table 201. The adapter 701 may be fixed to the shaping table 201 using, for example, screws and the like. Having a straddle shape, the adapter 701 may be simply put on the shaping table 201 without using the screws and the like.

The mounting surface 711 for the pattern forming sheet 207 of the adapter 701 is flush with the mounting surface for the pattern forming sheet 207 of the shaping table 201. This causes the distance between the optical engine 203 and the pattern forming sheet 207 to be constant and thus another calibration and adjustment of the optical engine 203 become unnecessary.

Since the present embodiment allows use of adapters, pattern forming sheets in various sizes may be used and it is thus possible to form patterns in various sizes. In addition, since the adapter has a straddle shape, it is possible to use pattern forming sheets in various sizes without fixing the adapter to the shaping table.

### Other Embodiments

While the present invention has been described with reference to the above embodiments, the present invention is not limited to these embodiments. Various modifications understood by those skilled in the art may be made to the present invention in the configuration and details withing the scope of the present invention. In addition, the scope of the present invention also includes all systems and devices that are made by any combination of separate characteristics included in the respective embodiments.

Still in addition, the present invention may be applied to a system configured from a plurality of devices or may be applied to a single device. Moreover, the present invention is also applicable to the case of supplying an information processing program to achieve the functions in embodiments directly or remotely to the system or the device. Accordingly, the scope of the present invention also includes a program installed in a computer to achieve the functions of the present invention by the computer, a medium having the program stored therein, and a WWW (world wide web) server to download the program. In particular, the scope of the present invention includes at least a non-transitory computer readable medium having a program causing a computer to execute the processing steps included in the above embodiments.

This application claims priority based upon the prior Japanese Patent Application No. 2017-161701, filed in Japan Patent Office on Aug. 25, 2017, the entire disclosure of which is incorporated herein by reference.

1. A pattern producing device, comprising:
a formation mechanism configured to form a pattern by irradiating a pattern forming sheet with a light beam;
a shaping table placed above the formation mechanism, having a first opening to pass the light beam, and configured to mount the pattern forming sheet thereon;
a column configured to attach the shaping table thereto; and
an adapter located in the shaping table and configured to mount the pattern forming sheet thereon for positioning of the pattern forming sheet on the first opening.

2. The pattern producing device according to claim 1, wherein the adapter positions at least a portion of the pattern forming sheet.

3. The pattern producing device according to claim 1, wherein the adapter partially closes the first opening.

4. The pattern producing device according to claim 1, wherein the adapter has a second opening to pass the light beam.

5. The pattern producing device according to claim 1, wherein the adapter is removably located in the shaping table.

6. The pattern producing device according to claim 1, wherein the adapter has a mounting surface for the pattern forming sheet flush with the shaping table.

7. The pattern producing device according to claim 1, wherein the adapter has an overhanging shape or a straddle shape.

8. The pattern producing device according to claim 1, wherein the first opening and a second opening have a shape including a rectangular shape.

9. The pattern producing device according to claim 1, further comprising a shaping mechanism configured to shape a three-dimensional shaped object by irradiating a material for the three-dimensional shaped object with the light beam.

10. The pattern producing device according to claim 9, wherein the shaping mechanism includes:
a material tank configured to store the material for the three-dimensional shaped object and removably located in the shaping table; and
a lifting head configured to lift the material irradiated with the light beam.

11. The pattern producing device according to claim 9, wherein the material includes a resin.
